(19) United States
(12) Patent Application Publication
(10) Pub. No.: US 2025/0318047 A1
(43) Pub. Date: Oct. 9, 2025

(54) WIRING CIRCUIT BOARD AND METHOD OF PRODUCING THE WIRING CIRCUIT BOARD

(71) Applicant: NITTO DENKO CORPORATION, Osaka (JP)

(72) Inventors: Akane KOMORI, Osaka (JP); Hayato TAKAKURA, Osaka (JP); Ryosuke SASAOKA, Osaka (JP)

(21) Appl. No.: 19/084,415

(22) Filed: Mar. 19, 2025

(30) Foreign Application Priority Data
Apr. 9, 2024 (JP) 2024-063001

(51) Int. Cl. H05K 1/02; H05K 3/18

(52) U.S. Cl. CPC H05K 1/0298; H05K 3/181

(57) ABSTRACT

A wiring circuit board includes a first insulating layer, a conductive pattern, a second insulating layer, and a first nickel layer disposed between a wire and the second insulating layer and covering the wire without covering the terminal. The first nickel layer contains phosphorus, and the content ratio of phosphorus in the first nickel layer is 6% by mass or less.

### CROSS-REFERENCE TO RELATED APPLICATION

The present application claims priority from Japanese Patent Application No. 2024-63001 filed on Apr. 9, 2024, the content of which is hereby incorporated by reference into this application.

### TECHNICAL FIELD

The present invention relates to a wiring circuit board and a method of producing the wiring circuit board.

### BACKGROUND ART

There have been known circuit boards each including an insulating layer, a conductive circuit disposed on the insulating layer, a cover layer covering the conductive circuit, and a metal thin film disposed between the conductive circuit and the cover layer. The metal thin film is made of nickel formed by electroless plating (for example, see Patent document 1 below).

### CITATION LIST

### Patent Document

Patent Document 1: Japanese Unexamined Patent Publication No. H 11-233906

### SUMMARY OF THE INVENTION

### Problem to be Solved by the Invention

In the circuit board described in Patent Document 1, the conductive circuit is formed, thereafter the metal thin film is formed on the entire surface of the conductive circuit, and then the cover layer is formed, and an unnecessary portion of the metal thin film is removed.

In this regard, when it takes excessive time to remove the metal thin film, there is a possibility that the producing efficiency is consequently decreased.

The present invention provides a wiring circuit board capable of suppressing corrosion of the wire while suppressing a decrease in producing efficiency, and a method of producing the wiring circuit board.

### Means for Solving the Problem

The present invention [1] includes a wiring circuit board including: a first insulating layer; a conductive pattern disposed on the first insulating layer and having a terminal and a wire; a second insulating layer disposed on the first insulating layer and covering the wire without covering the terminal; and a first nickel layer disposed between the wire and the second insulating layer and covering the wire without covering the terminal, wherein the first nickel layer contains phosphorus, and wherein a content ratio of phosphorus in the first nickel layer is 6% by mass or less.

According to such a configuration, the first nickel layer is disposed between the wire and the second insulating layer.

Therefore, the wire can be protected from the second insulating layer, and corrosion of the wire can be suppressed.

Furthermore, the content ratio of phosphorus in the first nickel layer is adjusted to 6% by mass or less.

Therefore, in the production of the wiring circuit board, the first nickel layer is formed so as to cover the wire and the terminal, and thereafter the first nickel layer covering the terminal can easily be removed by etching.

Therefore, after the formation of the first nickel layer, it is possible to suppress excessive time consumption of the removal of the first nickel layer covering the terminal, and it is possible to suppress a decrease in producing efficiency.

Overall, it is possible to suppress corrosion of the wire while suppressing a decrease in producing efficiency.

The present invention [2] includes the wiring circuit board described in the above-described [1], further including: a coating layer made of a metal different from the terminal and covering the terminal, wherein the coating layer has a second nickel layer different from the first nickel layer.

According to such a configuration, the second nickel layer suitable for protecting the terminal can be selected independently from the first nickel layer protecting the wire.

As a result, the degree of freedom in design of the wiring circuit board can be ensured.

The present invention [3] includes the wiring circuit board described in the above-described [2], wherein the second nickel layer contains phosphorus, and wherein a content ratio of phosphorus in the second nickel layer is more than 6% by mass.

According to such a configuration, the content ratio of phosphorus in the second nickel layer is adjusted to more than 6% by mass.

Therefore, when the terminal is made of copper, and a surface layer made of gold is formed on the second nickel layer, the diffusion of gold into the terminal can be suppressed.

The present invention [4] includes the wiring circuit board described in any one of the above-described [1] to [3], wherein the first nickel layer has a thickness of 300 nm or less.

According to such a configuration, it is possible to suppress the development of a crack in the wiring.

The present invention [5] includes the wiring circuit board described in any one of the above-described [1] to [4], wherein the first nickel layer is an electroless nickel-phosphorus plating layer.

The present invention [6] includes a method of producing the wiring circuit board described in any one of the above-described [1] to [5], the method including: a conductive pattern forming step of forming the conductive pattern on the first insulating layer; a first nickel layer forming step of forming the first nickel layer covering the wire and the terminal; a second insulating layer forming step of forming the second insulating layer on the first insulating layer; and a removal step of removing the first nickel layer covering the terminal by etching.

According to such a method, the first nickel layer can be formed between the wire and the second insulating layer.

Therefore, the wire can be protected from the second insulating layer, and corrosion of the wire can be suppressed.

Furthermore, the content ratio of phosphorus in the first nickel layer is adjusted to 6% by mass or less.

Therefore, in the first nickel layer forming step, the first nickel layer is formed so as to cover the wire and the terminal, and thereafter, in the removal step, the first nickel layer covering the terminal can easily be removed by etching.

Therefore, it is possible to suppress excessive time consumption of the removal step, and it is possible to suppress a decrease in producing efficiency.

Overall, it is possible to suppress corrosion of the wire while suppressing a decrease in producing efficiency.

The present invention [7] includes the method described in the above-described [6], wherein the first nickel layer is electroless plated on the wire and the terminal by using a catalyst in the first nickel layer forming step.

### Effects of the Invention

According to the wiring circuit board and the method of producing the wiring circuit board of the present invention, it is possible to suppress corrosion of the wire while suppressing a decrease in the producing efficiency.

### BRIEF DESCRIPTION OF THE DRAWINGS

FIG. 1 shows a plan view of one embodiment of the wiring circuit board of the present invention.

FIG. 2 is a cross-sectional view of the wiring circuit board shown in FIG. 1, taken along line A-A.

FIG. 3A shows a first insulating layer forming step of the method of producing the wiring circuit board shown in FIG. 2, FIG. 3B shows a step of forming a protective metal layer on the first insulating layer, following FIG. 3A, and FIG. 3C shows a step of forming a metal thin film on the protective metal layer, following FIG. 3B.

FIG. 4A shows a step of forming a conductive pattern on the metal thin film, following FIG. 3C, FIG. 4B shows a first nickel layer forming step, following FIG. 4A, and FIG. 4C shows a second insulating layer forming step, following FIG. 4B.

FIG. 5A shows the removal step, following FIG. 4C, FIG. 5B shows the step of forming a second nickel layer on the terminal, FIG. 5C shows the step of forming a surface layer on the second nickel layer.

### DESCRIPTION OF THE EMBODIMENT

### 1. Wiring Circuit Board

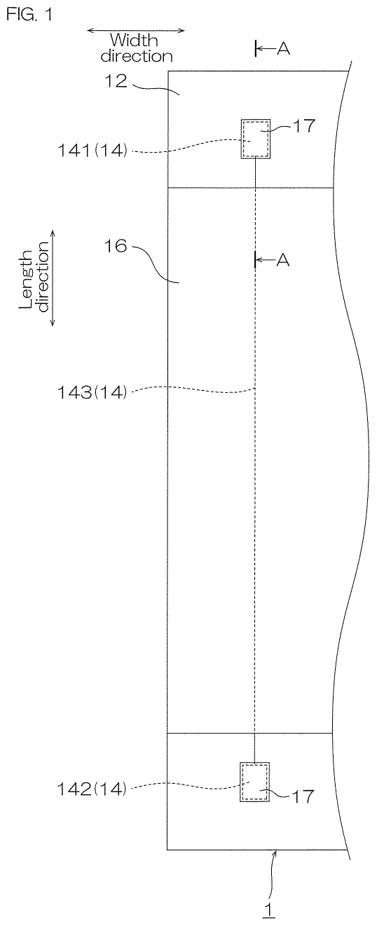

As shown in FIG. 1, a wiring circuit board 1 extends in a length direction and a width direction. In the present embodiment, the wiring circuit board 1 has a substantially rectangular shape. The shape of the wiring circuit board 1 is not limited to the present embodiment. The wiring circuit board 1 may be a flexible wiring circuit board or a suspension board with circuit.

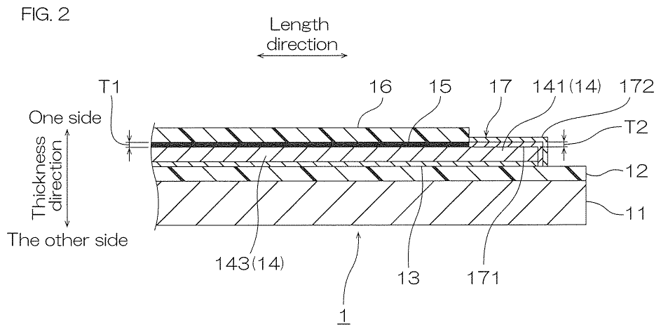

As shown in FIG. 2, the wiring circuit board 1 includes a metal support layer 11, a first insulating layer 12, a protective metal layer 13, a conductive pattern 14, a first nickel layer 15, a second insulating layer 16, and a coating layer 17.

### (1) Metal Support Layer

The metal support layer 11 supports the first insulating layer 12, the conductive pattern 14, and the secondary insulating layer 16. Examples of the material of the metal support layer 11 include stainless steel and a copper alloy.

The metal support layer 11 has a thickness of, for example, 10 μm to 1000 μm, preferably 50 μm to 200 μm.

### (2) First Insulating Layer

The first insulating layer 12 is disposed at one side of the metal support layer 11 in the thickness direction of the metal support layer 11. The thickness direction is orthogonal to the length direction and the width direction. The first insulating layer 12 is disposed on a one-side surface of the metal support layer 11 in the thickness direction. The first insulating layer 12 is disposed between the metal support layer 11 and the conductive pattern 14 in the thickness direction. The first insulating layer 12 can insulate the metal support layer 11 from the conductive pattern 14. The first insulating layer 12 is made of resin. Examples of the resin include polyimide, maleimide, epoxy resin, polybenzoxazole, and polyester. Preferably, the first insulating layer 12 is made of polyimide.

The first insulating layer 12 has a thickness of, for example, 3 μm to 50 μm, and preferably 5 μm to 20 μm.

### (3) Protective Metal Layer

The protective metal layer 13 is disposed between the first insulating layer 12 and the conductive pattern 14 in the thickness direction. The protective metal layer 13 is disposed on a one-side surface of the first insulating layer 12 in the thickness direction. The protective metal layer 13 protects the conductive pattern 14 from the first insulating layer 12. The protective metal layer 13 is made of a different metal from the conductive pattern 14. Examples of the material of the protective metal layer 13 include chromium, nickel, titanium, and an alloy thereof. As the material of the protective metal layer 13, preferably chromium is used.

### (4) Conductive Pattern

The conductive pattern 14 is disposed at one side of the first insulating layer 12 in the thickness direction. The conductive pattern 14 is disposed on the protective metal layer 13 in the thickness direction. In other words, the conductive pattern 14 is disposed on the one-side surface of the first insulating layer 12 through the protective metal layer 13 in the thickness direction. The conductive pattern 14 is disposed on the opposite side to the metal support layer 11 with respect to the first insulating layer 12 in the thickness direction. The conductive pattern 14 is made of metal. Examples of the metal include, for example, copper, silver, gold, iron, aluminum, and an alloy thereof. The conductive pattern 14 is preferably made of copper.

The conductive pattern 14 has a thickness of, for example, 3 μm to 70 μm, and preferably 5 μm to 30 μm.

As illustrated in FIG. 1, the conductive pattern 14 includes a terminal 141, a terminal 142, and a wire 143. The number of terminals and the number of wires are not limited.

The terminal 141 is disposed at one end portion of the wiring circuit board 1 in the length direction. The terminal 141 has, for example, a square land shape.

The terminal 142 is disposed at the other end portion of the wiring circuit board 1 in the length direction. The terminal 142 has, for example, a square land shape.

One end of the wire 143 is connected to the terminal 141. The other end of the wire 143 is connected to the terminal 142. The wire 143 electrically connects the terminal 141 and the terminal 142.

The width of the wire 143 is narrower than the width of the terminals 141 and 142. The wire 143 has a width of, for example, 5 μm to 100 μm, and preferably 8 μm to 50 μm.

### (4) First Nickel Layer

As shown in FIG. 2, the first nickel layer 15 is disposed between the wire 143 and the second insulating layer 16. The first nickel layer 15 covers the wire 143. The first nickel layer 15 entirely covers the portions of the wire 143 covered by the second insulating layer 16. Specifically, the first nickel layer 15 covers all of a one-side surface of the wire 143 in the thickness direction and both side surfaces of the wire 143 in the width direction. The first nickel layer 15 protects the wire 143 from the second insulating layer 16. The first nickel layer 15 does not cover the terminals 141 and 142.

The first nickel layer 15 contains phosphorus. Specifically, the first nickel layer 15 is made of a nickel-phosphorus alloy. The first nickel layer 15 is preferably an electroless nickel-phosphorus plating layer.

The content ratio of phosphorus in the first nickel layer 15 is 6% by mass or less, preferably 4% by mass or less and, for example, more than 0% by mass, preferably 1% by mass or more.

When the content ratio of phosphorus in the first nickel layer 15 is the above-described upper limit or less, the first nickel layer 15 on the terminals 141 and 142 can be efficiently removed by etching in a removal step of the method of producing the wiring circuit board to be described later.

When the content ratio of phosphorus in the first nickel layer 15 is the above-described lower limit or more, corrosion of the wire 143 can be suppressed.

A thickness T1 of the first nickel layer 15 is, for example, 500 nm or less, preferably 300 nm or less, and, for example, 1 nm or more, preferably 50 nm or more.

When the thickness T1 of the first nickel layer 15 is the above-described upper limit or less, it is possible to suppress the development of a crack in the wire 143.

When the thickness T1 of the first nickel layer 15 is the above-described lower limit or more, it is possible to suppress corrosion of the wire 143.

### (5) Second Insulating Layer

As shown in FIGS. 1 and 2, the second insulating layer 16 is disposed on the first insulating layer 12 in the thickness direction. The second insulating layer 16 covers the wire 143. The second insulating layer 16 does not cover the terminals 141 and 142. The second insulating layer 16 is made of resin. Examples of the resin include polyimide, maleimide, epoxy resin, polybenzoxazole, and polyester.

### (6) Coating Layer

The coating layer 17 covers the terminal 141. Specifically, the coating layer 17 covers all of a one-side surface of the terminal 141 in the thickness direction and both side surfaces of the terminal 141 in the width direction. The coating layer 17 is made of a different metal from the terminal 141. The coating layer 17 may be a single layer or a plurality of layers. The coating layer 17 is preferably a plurality of layers, and includes a second nickel layer 171 and a surface layer 172.

The second nickel layer 171 covers the terminal 141. Specifically, the second nickel layer 171 covers all of the one-side surface of the terminal 141 in the thickness direction and both side surfaces of the terminal 141 in the width direction. The second nickel layer 171 is disposed between the terminal 141 and the surface layer 172. The second nickel layer 171 contains phosphorus. Specifically, the second nickel layer 171 is made of, for example, a nickel-phosphorus alloy. The second nickel layer 171 is preferably an electroless nickel-phosphorus plating layer. The second nickel layer 171 is different from the first nickel layer 15. Specifically, the content ratio of phosphorus in the second nickel layer 171 is different from the content ratio of phosphorus in the first nickel layer 15.

The content ratio of phosphorus in the second nickel layer 171 is higher than the content ratio of phosphorus in the first nickel layer 15. Specifically, the content ratio of phosphorus in the second nickel layer 171 is, for example, more than 6% by mass, preferably 7% by mass or more, and more preferably 9% by mass or more.

When the content ratio of phosphorus in the second nickel layer 171 is the above-described lower limit or more, and the surface layer 172 is made of gold, it is possible to suppress the diffusion of the gold of the surface layer 172 into the terminal 141.

A thickness T2 of the second nickel layer 171 is larger than the thickness T1 of the first nickel layer 15. The thickness T2 of the second nickel layer 171 is, for example, more than 50 nm, preferably 100 nm or more, and for example, 1000 nm or less, preferably 600 nm or less.

When the thickness of the second nickel layer 171 is larger than the above-described lower limit, and the surface layer 172 is made of gold, it is possible to suppress the diffusion of the gold of the surface layer 172 into the terminal 141.

The surface layer 172 covers the second nickel layer 171. The surface layer 172 is made of a different metal from the conductive pattern 14 and the second nickel layer 171. The surface layer 172 is made of, for example, gold. The surface layer 172 is preferably an electroless gold plating layer.

The coating layer 17 described above is also provided on the terminal 142 (see FIG. 1).

### 2. Method of Producing Wiring Circuit Board

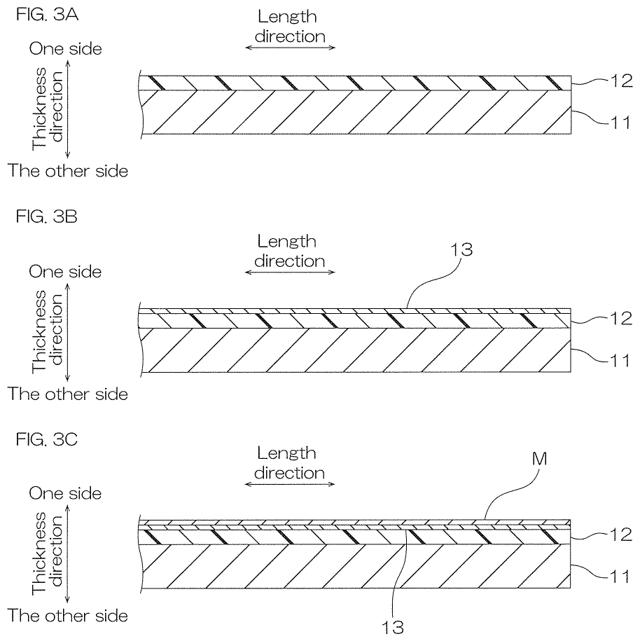

Referring to FIGS. 3A to 5C, a method for producing the circuit board 1 is described below.

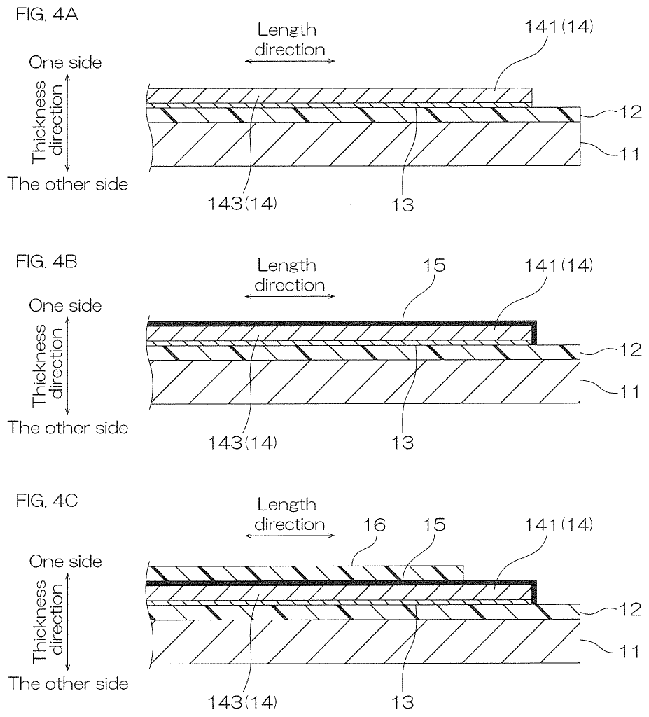

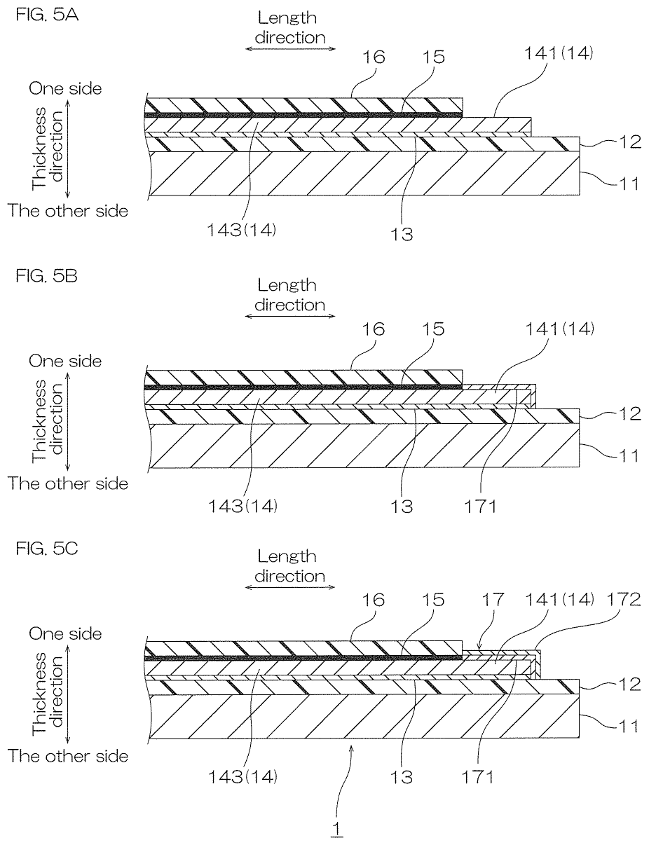

The method of producing the wiring circuit board 1 includes a first insulating layer forming step (see FIG. 3A), a conductive pattern forming step (see FIGS. 3B to 4A), a first nickel layer forming step (see FIG. 4B), a second insulating layer forming step (see FIG. 4C), a removal step (see FIG. 5A), and a coating layer forming step (see FIGS. 5B and 5C).

### (1) First Insulating Layer Forming Step

As shown in FIG. 3A, in the first insulating layer forming step, a first insulating layer 12 is formed on a one-side surface of a metal support layer 11.

Specifically, in the first insulating layer forming step, first, a solution (varnish) of a photosensitive resin is applied onto the metal support layer 11 and dried to form a coating film of the photosensitive resin. Next, the coating film of the photosensitive resin is exposed to light and developed. In this manner, the first insulating layer 12 is obtained.

### (2) Conductive Pattern Forming Step

Next, in the conductive pattern forming step, a protective metal layer 13 and a conductive pattern 14 are formed on the first insulating layer 12.

Specifically, as shown in FIGS. 3B and 3C, first, a seed layer is formed on a one-side surface of the first insulating layer 12 and on a one-side surface of the metal support layer 11 in the thickness direction. In the present embodiment, the seed layer includes a protective metal layer 13 and a conductive thin film M. The protective metal layer 13 is disposed on the one-side surface of the first insulating layer 12 and the one-side surface of the metal support layer 11.

The conductive thin film M is disposed on a one-side surface of the protective metal layer 13. The protective metal layer 13 and the conductive thin film M are formed by sputtering. That is, the protective metal layer 13 and the conductive thin film M are formed in order on the first insulating layer and the metal support layer by sputtering. The conductive thin film M is made of the same material as the material of the conductive pattern 14. The conductive thin film M forms a part of the conductive pattern 14.

Next, a plating resist is attached to a one-side surface of the conductive thin film M in the thickness direction. The plating resist covers the conductive thin film M.

Next, the plating resist is exposed to light and developed. Then, the plating resist in the portion where a conductive pattern 14 is to be formed is removed, and the conductive thin film M is exposed in the portion where the conductive pattern 14 is to be formed. On the other hand, the plating resist in the portion where the conductive pattern 14 is not formed remains.

Next, a conductive pattern 14 is formed on the exposed conductive thin film M by electrolytic plating. After the electrolytic plating is completed, the plating resist is released, and the seed layer (the conductive thin film M and the protective metal layer 13) exposed due to the release of the plating resist is removed by etching.

In this manner, as shown in FIG. 4A, the protective metal layer 13 and the conductive pattern 14 are formed on the first insulating layer 12.

### (3) First Nickel Layer Forming Step

Next, as shown in FIG. 4B, in the first nickel layer forming step, a first nickel layer 15 is formed. In the first nickel layer forming step, a first nickel layer is formed on the entire surface of the conductive pattern 14 by electroless plating. In other words, in the first nickel layer forming step, the first nickel layer 15 is electroless plated on the wire 143 and the terminals 141 and 142.

A plating solution (first plating solution) used in the first nickel layer forming step contains a nickel salt and a phosphine acid salt as a reducing agent. Examples of the nickel salt include nickel sulfate. Examples of the phosphine acid salt include sodium phosphinate. The first plating solution may contain a buffer. The buffer is not limited as long as it can stabilize pH of the first plating solution.

The blending ratio of the nickel salt in the first plating solution is, for example, 0.1% by mass to 2.0% by mass, preferably 0.5% by mass to 1.5% by mass.

The blending ratio of the reducing agent in the first plating solution is, for example, 0.1% by mass to 2.0% by mass, preferably 0.5% by mass to 1.5% by mass.

In the first nickel layer forming step, the growth of the first nickel layer 15 is promoted by adding a catalyst to the first plating solution. That is, in the first nickel layer forming step, electroless plating is carried out using a catalyst.

When the reducing agent is a phosphine acid salt, for example, palladium, iron, nickel, and zinc are used as the catalyst.

The temperature of the first plating solution is, for example, 20° C. to 80° C., preferably 30° C. to 65° C., and more preferably 50° C. to 60° C.

The content ratio of phosphorus in the first nickel layer 15 can be adjusted to 6% by mass or less by carrying out the electroless plating in the above-described temperature range of the first plating solution by using the first plating solution having the above-described composition. Further, by increasing the temperature of the first plating solution, the content ratio of phosphorus in the first nickel layer 15 can be reduced.

The first nickel layer 15 obtained in the first nickel layer forming step covers the wire 143 and the terminals 141 and 142.

### (4) Second Insulating Layer Forming Step

Next, as shown in FIG. 4C, in the second insulating layer forming step, a second insulating layer 16 is formed on the first insulating layer 12.

Specifically, in the second insulating layer forming step, first, a solution (varnish) of a photosensitive resin is applied on the first nickel layer 15 and the first insulating layer 12 and dried to form a coating film of the photosensitive resin.

Next, the coating film of the photosensitive resin is exposed to light and developed. In this manner, a second insulating layer 16 covering the first nickel layer 15 is formed on the first insulating layer 12.

### (5) Removal Step

Next, as shown in FIG. 5A, in the removal step, the first nickel layer 15 covering the terminals 141 and 142 are removed.

To remove the first nickel layer 15, the first nickel layer 15 is etched, for example, by acid. Examples of the acid include nitric acid.

At the time, since the content ratio of phosphorus in the first nickel layer 15 is adjusted to 6% by mass or less, the first nickel layer 15 can be efficiently removed by the acid.

### (6) Coating Layer Forming Step

Next, in the coating layer forming step, a coating layer 17 is formed on the surfaces of the terminals 141 and 142.

Specifically, as shown in FIG. 5B, in the coating layer forming step, a second nickel layer 171 is formed on the surfaces of the terminals 141 and 142 by electroless plating.

A plating solution (second plating solution) used for forming the second nickel layer 171 also contains a nickel salt and a phosphine acid salt as a reducing agent in the same manner as the first plating solution used in the first nickel layer forming step. Examples of the nickel salt include nickel sulfate. Examples of the phosphine acid salt include sodium phosphinate. The second plating solution may contain a buffer. The buffer is not limited as long as it can stabilize pH of the second plating solution.

The blending ratio of the nickel salt in the second plating solution is, for example, 3% by mass to 7% by mass, preferably 4% by mass to 6% by mass.

The blending ratio of the reducing agent in the second plating solution is, for example, 1% by mass to 5% by mass, preferably 1% by mass to 3% by mass.

In the step of forming the second nickel layer, in the same manner as the first nickel layer forming step, the above-described catalyst is added to the second plating solution to promote the growth of the second nickel layer 171.

The temperature of the second plating solution is, for example, 80° C. to 90° C.

By carrying out electroless plating in the above-described temperature range of the second plating solution by using the second plating solution having the above-described composition, the content ratio of phosphorus in the second nickel layer 171 can be more than 6% by mass.

Next, as shown in FIG. 5C, a surface layer 172 is formed on the second nickel layer 171 by electroless gold plating.

As described above, a wiring circuit board 1 can be obtained.

### 3. Operations and Effects

(1) According to the wiring circuit board 1, as shown in FIG. 2, the first nickel layer 15 is disposed between the wire 143 and the second insulating layer 16.

Therefore, the wire 143 can be protected from the second insulating layer 16, and corrosion of the wire 143 can be suppressed.

Furthermore, the content ratio of phosphorus in the first nickel layer 15 is adjusted to 6% by mass or less.

Therefore, as shown in FIG. 4B, in the first nickel layer forming step, the first nickel layer 15 is formed so as to cover the wire 143 and the terminals 141 and 142, and thereafter, as shown in FIG. 5A, in the removal step, the first nickel layer 15 covering the terminals 141 and 142 can easily be removed by etching.

Therefore, it is possible to suppress excessive time consumption of the removal step, and it is possible to suppress a decrease in producing efficiency.

In summary, it is possible to suppress corrosion of the wire 143 while suppressing a decrease in producing efficiency.

(2) According to the wiring circuit board 1, as shown in FIG. 2, the coating layer 17 covering the terminals 141 and 142 has a second nickel layer 171 different from the first nickel layer 15.

Therefore, a second nickel layer 171 suitable for protecting the terminals 141 and 142 can be selected independently from the first nickel layer 15 protecting the wire 143.

As a result, the degree of freedom in design of the wiring circuit board 1 can be ensured.

(3) According to the wiring circuit board 1, the content ratio of phosphorus in the second nickel layer 171 is adjusted to more than 6% by mass.

Therefore, when the terminals 141 and 142 are made of copper, and a surface layer 172 made of gold is formed on the second nickel layer 171, it is possible to suppress the diffusion of the gold into the terminals 141 and 142.

(4) According to the wiring circuit board 1, the thickness T1 of the first nickel layer 15 is 300 nm or less.

Therefore, it is possible to suppress the development of a crack in the wire 143.

### 4. Modified Examples

Modified examples are described. In the variations, the same members as the above-described embodiment are given the same numerical references and the detailed descriptions thereof are omitted.

(1) The wiring circuit board 1 may not have a coating layer 17.

(2) The method of forming the first nickel layer 15 is not limited to electroless plating as long as a nickel-phosphorus alloy can be formed.

(3) The wiring circuit board 1 may not have a metal support layer 11.

### EXAMPLES

The present invention is more specifically described with reference to Example and Comparative Example below. The present invention is not limited to Example and Comparative Example in any way. The specific numeral values used in the description below, such as volume ratios (content ratios), physical property values, and parameters, can be replaced with the upper limit values (numeral values defined with “or less”, and “less than”) or the lower limit values (numeral values defined with “or more”, and “more than”) of the corresponding volume ratios (content ratios), physical property values, and parameters in the above-described “DESCRIPTION OF THE EMBODIMENT”.

### 1. Production of Wiring Circuit Board

### (1) Example 1

First, a solution (varnish) of photosensitive polyimide (photosensitive resin) was applied onto a metal support layer made of a copper alloy and dried to form a coating film of the photosensitive polyimide. Next, the coating film of the photosensitive polyimide was exposed to light and developed. In this manner, a first insulating layer made of polyimide was formed on the metal support layer (first insulating layer forming step, see FIG. 3A).

Next, a seed layer was formed on the first insulating layer and the metal support layer. Specifically, a protective metal layer made of chromium and a conductive thin film made of copper were formed in order on the first insulating layer and the metal support layer by sputtering (see FIG. 3B and FIG. 3C). The seed layer consists of the protective metal layer and the conductive thin film.

Next, a plating resist was attached to a one-side surface of the conductive thin film, and the plating resist was exposed to light and developed. Then, the plating resist was removed in the portion where a conductive pattern was to be formed, and the conductive thin film was exposed in the portion where a conductive pattern was to be formed.

Next, a conductive pattern made of copper was formed on the exposed conductive thin film by electrolytic plating (see FIG. 4A). After the electrolytic plating was completed, the plating resist was released, and the seed layer (the conductive thin film and the protective metal layer) exposed due to the release of the plating resist was removed by etching. In this manner, the protective metal layer and the conductive pattern were formed on the first insulating layer (conductive pattern forming step).

Next, a first nickel layer was formed on the entire surface of the conductive pattern by electroless nickel-phosphorus plating (first nickel layer forming step, see FIG. 4B).

Next, a solution (varnish) of photosensitive polyimide was applied onto the first nickel layer and the first insulating layer and dried to form a coating film of the photosensitive polyimide. Next, the coating film of the photosensitive polyimide was exposed to light and developed, and a second insulating layer covering the first nickel layer was formed on the first insulating layer (second insulating layer forming step, see FIG. 4C).

Next, the first nickel layer covering the terminal was removed by etching at 30° C. using acid (nitric acid) (removal step, see FIG. 5A).

Next, a second nickel layer was formed on the surface of the terminal by electroless nickel-phosphorus plating (see FIG. 5B). Next, a surface layer made of gold was formed on the second nickel layer by electroless gold plating (see FIG. 5C).

As described above, a wiring circuit board was obtained.

Table 1 shows the composition of the plating solution (first plating solution) used for forming the first nickel layer, the temperature of the first plating solution, the thickness of the formed first nickel layer, the content ratio of phosphorus in the formed first nickel layer, the etchability of the first nickel layer in the removal step, the composition of the plating solution (second plating solution) used for forming the second nickel layer, the temperature of the second plating solution, the thickness of the formed second nickel layer, and the content ratio of phosphorus in the formed second nickel layer.

The etchability of the first nickel layer in the removal step was evaluated by the following criteria for evaluation.

### <Criteria for Evaluation of Etchability>

A: The first nickel layer was completely removed.

B: The first nickel layer remained.

The content ratio of phosphorus was determined by fluorescence X-ray analysis based on a standard sample whose content ratio of phosphorus was known.

### (2) Examples 2 and 3

A wiring circuit board was produced in the same manner as in Example 1 except that the temperature of the first plating solution was changed to the temperature shown in Table 1. The results are shown in Table 1.

### (3) Examples 4 to 6

A wiring circuit board was produced in the same manner as in Example 1 except that the composition and the temperature of the second plating solution were changed to the composition and the temperature shown in Table 2. The results are shown in Table 2.

### (4) Example 7

A wiring circuit board was produced in the same manner as in Example 1 except that the second nickel layer was formed by electrolytic plating. The results are shown in Table 2.

### (5) Example 8

A wiring circuit board was produced in the same manner as in Example 1 except that the thickness of the first nickel layer was changed to 600 nm. The results are shown in Table 2.

### (6) Comparative Example 1

A wiring circuit board was produced in the same manner as in Example 1 except that the first nickel layer was not formed. The results are shown in Table 3.

### (7) Comparative Example 2

A wiring circuit board was produced in the same manner as in Example 1 except that the first nickel layer was formed by electrolytic plating. The results are shown in Table 3.

### (8) Comparative Example 3

A wiring circuit board was produced in the same manner as in Example 1 except that the first nickel layer was formed by electroless nickel-boron plating (reducing agent: dimethylamine borane). The results are shown in Table 3.

### (9) Comparative Examples 4 and 5

A wiring circuit board was produced in the same manner as in Example 1 except that the composition and the temperature of the first plating solution were changed to the composition and the temperature shown in Table 3. The results are shown in Table 3.

### 2. Inspection of Wiring Circuit Board

### (1) Corrosion Resistance of Wire

A random vibration test specified in JIS Z0232:2020 was carried out in the test conditions changed to Accelerated Power Spectral Density: 0 33 g²/Hz, Frequency: 5 to 500 Hz, Test Time: 2000 minutes.

Thereafter, the wire was observed with a camera (CCD camera), and the corrosion resistance of the wire was evaluated based on the following criteria for evaluation. The results are shown in Tables 1 to 3.

### <Criteria for Evaluation>

A: There was no discoloring of the wire.

B: The wire was discolored.

### (2) Wire Reliability Test

Regarding the reliability of the wire, the resistance value of the wire was measured before and after the above-described random vibration test, and evaluated based on the following criteria for evaluation. The results are shown in Tables 1 to 3.

### <Criteria for Evaluation>

A: The rate of change in resistance value before and after the vibration test was less than 20%.

B: The rate of change in resistance value before and after the vibration test was 20% or more and less than 100%.

C: The rate of change in resistance value before and after the vibration test was 100% or more.

### (3) Adhesion of Second Insulating Layer to First Nickel Layer

The adhesion of the second insulating layer to the first nickel layer was evaluated by subjecting the second insulating layer to a cross-cut test specified in JIS K5600-5-6:1999. The results are shown in Tables 1 to 3.

### <Criteria for Evaluation>

A: The second insulating layer was not peeled off.

B: The second insulating layer was peeled off.

### (4) Diffusibility of Gold Plating Layer (Surface Layer of Coating Layer) of Terminal

The diffusivity of the gold plating layer (the surface layer of the coating layer) was evaluated by subjecting a solder placed on the terminal to a shear strength test specified in JIS C62137-1-2:2010. The results are shown in Tables 1 to 3.

### <Criteria for Evaluation>

A: The share strength was 1200 gf or more.

B: The share strength was 1000 gf or more and less than 1200 gf.

C: The share strength was less than 1000 gf.

TABLE 1
Table 1

| | | | Ex. 1 | Ex. 2 | Ex. 3 |
|---|---|---|---|---|---|
| First | Nickel salt | Nickel sulfate | 1 | 1 | 1 |
| plating | (% by mass) | Nickel chloride | | | |
| solution | Reducing agent | Sodium phosphinate | 1 | 1 | 1 |
| | (% by mass) | Dimethylamine borane | | | |
| | Catalyst | | Pd | Pd | Pd |
| | Temperature (° C.) | | 55 | 70 | 25 |
| Second | Nickel salt | Nickel sulfate | 5 | 5 | 5 |
| plating | (% by mass) | Nickel chloride | | | |
| solution | Reducing agent | Sodium phosphinate | 2 | 2 | 2 |
| | (% by mass) | | | | |

| | | | | |
|---|---|---|---|---|
| | Catalyst | Pd | Pd | Pd |
| | Temperature (° C.) | 85 | 85 | 85 |
| First | Thickness (nm) | 300 | 300 | 300 |
| nickel | Content ratio of phosphorus (% by mass) | 3 | 2 | 5 |
| layer | | | | |
| Second | Thickness (nm) | 500 | 500 | 500 |
| nickel | Content ratio of phosphorus (% by mass) | 10 | 10 | 10 |
| layer | | | | |

| | | | |
|---|---|---|---|
| Etchability of first nickel layer | A | A | A |
| Corrosion resistance of wire | A | A | A |
| Reliability of wire | A | A | A |
| Adhesion of second insulating layer to first nickel layer | A | A | A |
| Diffusivity of gold plating on terminal | A | A | A |

TABLE 2
Table 2

| | | | Ex. 4 | Ex. 5 | Ex. 6 | Ex. 7 | Ex. 8 |
|---|---|---|---|---|---|---|---|
| First | Nickel salt | Nickel sulfate | 1 | 1 | 1 | 1 | 1 |
| plating | (% by mass) | Nickel chloride | | | | | |
| solution | Reducing agent | Sodium phosphinate | 1 | 1 | 1 | 1 | 1 |
| | (% by mass) | Dimethylamine borane | | | | | |
| | Catalyst | | Pd | Pd | Pd | Pd | Pd |
| | Temperature (° C.) | | 55 | 55 | 55 | 55 | 55 |
| Second | Nickel salt | Nickel sulfate | 5 | 1 | 1 | 7 | 5 |
| plating | (% by mass) | Nickel chloride | | | | 2 | |
| solution | Reducing agent | Sodium phosphinate | 2 | 1 | 1 | | 2 |
| | (% by mass) | | | | | | |

| | | | | | | |
|---|---|---|---|---|---|---|
| | Catalyst | Pd | Pd | Pd | | Pd |
| | Temperature (° C.) | 85 | 25 | 25 | 55 | 85 |
| First | Thickness (nm) | 300 | 300 | 300 | 300 | 600 |
| nickel | Content ratio of | 3 | 3 | 3 | 3 | 3 |
| layer | phosphorus (% by mass) | | | | | |
| Second | Thickness (nm) | 150 | 500 | 150 | 1000 | 500 |
| nickel | Content ratio of | 10 | 5 | 5 | 0 | 10 |
| layer | phosphorus (% by mass) | | | | | |

| | | | | | |
|---|---|---|---|---|---|
| Etchability of first nickel layer | A | A | A | A | A |
| Corrosion resistance of wire | A | A | A | A | A |
| Reliability of wire | A | A | A | A | C |
| Adhesion of second insulating layer to first nickel layer | A | A | A | A | A |
| Diffusivity of gold plating on terminal | A | B | C | A | A |

TABLE 3
Table 3

| | | | Comp. | Comp. | Comp. | Comp. | Comp. |
|---|---|---|---|---|---|---|---|
| | | | Ex. 1 | Ex. 2 | Ex. 3 | Ex. 4 | Ex. 5 |
| First | Nickel salt | Nickel sulfate | | 7 | 1 | 5 | 5 |
| plating | (% by mass) | Nickel chloride | | 2 | | | |
| solution | Reducing agent | Sodium phosphinate | | | | 2 | 2 |
| | (% by mass) | Dimethylamine borane | | | 1 | | |
| | Catalyst | | | | Pd | Pd | Pd |
| | Temperature (° C.) | | | 55 | 60 | 84 | 85 |
| Second | Nickel salt | Nickel sulfate | 5 | 5 | 5 | 5 | 5 |
| plating | (% by mass) | Nickel chloride | | | | | |
| solution | Reducing agent | Sodium phosphinate | 2 | 2 | 2 | 2 | 2 |
| | (% by mass) | | | | | | |

| | | | | | | |
|---|---|---|---|---|---|---|
| | Catalyst | Pd | Pd | Pd | Pd | Pd |
| | Temperature (° C.) | 85 | 85 | 85 | 85 | 85 |
| First | Thickness (nm) | | 300 | 300 | 300 | 300 |
| nickel | Content ratio of | | 0 | 0 | 8 | 13 |
| layer | phosphorus (% by mass) | | | | | |
| Second | Thickness (nm) | 500 | 500 | 500 | 500 | 500 |
| nickel | Content ratio of | 10 | 10 | 10 | 10 | 10 |
| layer | phosphorus (% by mass) | | | | | |

| | | | | | |
|---|---|---|---|---|---|
| Etchability of first nickel layer | | A | A | B | B |
| Corrosion resistance of wire | B | B | B | A | A |
| Reliability of wire | C | B | B | A | A |
| Adhesion of second insulating layer to first nickel layer | B | A | A | A | A |
| Diffusivity of gold plating on terminal | A | A | A | A | A |

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICABILITY

The wiring circuit board of the present invention can be used for connecting electronic components. The method of producing the wiring circuit board of the present invention can be used for producing wiring circuit boards.

### DESCRIPTION OF REFERENCE NUMERALS

1 Wiring circuit board
12 First insulating layer
14 Conductive pattern
141 Terminal
143 Wire
15 First nickel layer
16 Secondary insulating layer
17 Coating layer
171 Second nickel layer
172 Surface layer

1. A wiring circuit board comprising:
a first insulating layer;
a conductive pattern disposed on the first insulating layer and having a terminal and a wire;
a second insulating layer disposed on the first insulating layer and covering the wire without covering the terminal; and
a first nickel layer disposed between the wire and the second insulating layer and covering the wire without covering the terminal,
wherein the first nickel layer contains phosphorus, and
wherein a content ratio of phosphorus in the first nickel layer is 6% by mass or less.

2. The wiring circuit board according to claim 1, further comprising:
a coating layer made of a metal different from the terminal and covering the terminal, wherein the coating layer has a second nickel layer different from the first nickel layer.

3. The wiring circuit board according to claim 2,
wherein the second nickel layer contains phosphorus, and
wherein a content ratio of phosphorus in the second nickel layer is more than 6% by mass.

4. The wiring circuit board according to claim 1,
wherein the first nickel layer has a thickness of 300 nm or less.

5. The wiring circuit board according to claim 1,
wherein the first nickel layer is an electroless nickel-phosphorus plating layer.

6. A method of producing the wiring circuit board according to claim 1, the method comprising:
a conductive pattern forming step of forming the conductive pattern on the first insulating layer;
a first nickel layer forming step of forming the first nickel layer covering the wire and the terminal;
a second insulating layer forming step of forming the second insulating layer on the first insulating layer; and
a removal step of removing the first nickel layer covering the terminal by etching.

7. The method according to claim 6, wherein the first nickel layer is electroless plated on the wire and the terminal by using a catalyst in the first nickel layer forming step.
